(19) United States
(12) Patent Application Publication
(10) Pub. No.: US 2024/0130195 A1
(43) Pub. Date: Apr. 18, 2024

(54) LAMINATED LIGHT-EMITTING UNIT AND PRODUCTION METHOD THEREOF, AND DISPLAY PANEL

(71) Applicant: Xiamen Extremely PQ Display Technology Co., Ltd., Xiamen (CN)

(72) Inventor: YONG FAN, Xiamen (CN)

(21) Appl. No.: 18/398,436

(22) Filed: Dec. 28, 2023

Related U.S. Application Data
(63) Continuation of application No. PCT/CN2021/136839, filed on Dec. 9, 2021.

(51) Int. Cl. H10K 59/70; H10K 59/12

(52) U.S. Cl. CPC H10K 59/70; H10K 59/1201

(57) ABSTRACT

A laminated light-emitting unit includes a first light-emitting component including a top surface, a bottom surface opposite to the top surface and multiple side surfaces disposed between the top surface and the bottom surface, a second light-emitting component laminated on the top surface of the first light-emitting component, a common electrode disposed on a first side surface of the multiple side surfaces, connected to negative electrodes of the first light-emitting component and the second light-emitting component and extending to the bottom surface of the first light-emitting component, a second electrode disposed on a second side surface of the multiple side surfaces, the first side surface and the second side surface are different side surfaces, the second electrode is electrically connected to a positive electrode of the second light-emitting component and insulated from the first light-emitting component, and the second electrode extends to the bottom surface of the first light-emitting component.

### CROSS-REFERENCE TO RELATED APPLICATION

This application is a continuation of International Application No. PCT/CN2021/136839, filed on Dec. 9, 2021. The international Application claims priority from Chinese patent application No. 202111530054.5, filed on Dec. 9, 2021. The entire contents of the above-mentioned applications are hereby incorporated herein by reference.

### TECHNICAL FIELD

The disclosure relates to the field of display technologies, and particularly to a laminated light-emitting unit and a production method thereof, and a display panel.

### BACKGROUND

Due to the characteristic of self-luminous without backlight, more and more display panels are choosing to use new display technologies such as micro light-emitting diode (micro-LED) display and organic light-emitting diode (OLED) display. Each light-emitting unit of the new display technologies can correspond to a sub-pixel, for example, in an existing RGB display panel, each pixel unit includes a red (R) light-emitting unit, a green (G) light-emitting unit and a blue (B) light-emitting unit, which respectively correspond to R/G/B sub-pixels. By controlling the corresponding light-emitting unit of each sub-pixel, a full color effect can be achieved, that is, in the existing RGB display panel, each pixel needs to be composed of three light points (light-emitting units). When a display panel with more colors such as four color display is needed, each pixel needs to be composed of more light points, and each pixel occupies a larger area. In addition, this structure can cause significant color deviation in narrow visual angle applications of display panels.

Therefore, it is urgent to provide a new display panel to improve the display effect of the existing display panels.

### SUMMARY

Therefore, in order to overcome at least some defects in the related art, embodiments of the disclosure provide a laminated light-emitting unit and a production method thereof, and a display panel, which have the characteristics of improving display resolution, narrow visual angle display, and low color deviation.

Specifically, in an aspect, an embodiment of the disclosure provides a laminated light-emitting unit including a first light-emitting component, a second light-emitting component, a common electrode, a first electrode and a second electrode. The first light-emitting component includes a top surface, a bottom surface opposite to the top surface and multiple side surfaces disposed between the top surface and the bottom surface. The second light-emitting component is laminated on the top surface of the first light-emitting component. The common electrode is disposed on a first side surface of the multiple side surfaces and two ends of the common electrode are connected to a negative electrode of the first light-emitting component and a negative electrode of the second light-emitting component, and the common electrode extends to the bottom surface of the first light-emitting component. The second electrode is disposed on a second side surface of the multiple side surfaces, the first side surface and the second side surface are different side surfaces, the second electrode is electrically connected to a positive electrode of the second light-emitting component and insulated from the first light-emitting component, and the second electrode extends to the bottom surface of the first light-emitting component. The first electrode is spaced apart from the common electrode and the second electrode, and the first electrode is electrically connected to a positive electrode of the first light-emitting component and insulated from the second light-emitting component.

In an embodiment, the laminated light-emitting unit further includes a third light-emitting component and a third electrode. The third light-emitting component is laminated on a side of the second light-emitting component facing away from the first light-emitting component. The third electrode is spaced apart from the first electrode, the second electrode and the common electrode, the third electrode is disposed on a third side surface of the multiple side surfaces. The third side surface and the first side surface are different sides, the third electrode is electrically connected to a positive electrode of the third light-emitting component and insulated from the first light-emitting component and the second light-emitting component, and the third electrode extends to the bottom surface of the first light-emitting component. The common electrode is electrically connected to a negative electrode of the third light-emitting component, the first electrode and the second electrode are insulated from the third light-emitting component, and the first electrode is disposed on the bottom surface of the first light-emitting component.

In an embodiment, the first light-emitting component and the second light-emitting component are inorganic light-emitting structures, and the first electrode is disposed on the second side surface and extends to the bottom surface of the first light-emitting component or disposed on the bottom surface of the first light-emitting component. Or the second light-emitting component is an inorganic light-emitting structure, the first light-emitting component is an organic light-emitting structure, and the first electrode is disposed on the bottom surface of the first light-emitting component.

In an embodiment, the first light-emitting component, the second light-emitting component and the third light-emitting component are inorganic light-emitting structures.

In an embodiment, the second light-emitting component and the third light-emitting component are inorganic light-emitting structures, and the first light-emitting component is an organic light-emitting structure.

In an embodiment, the first light-emitting component is a red light-emitting component, the second light-emitting component is a green light-emitting component, and the third light-emitting component is a blue light-emitting component.

In an embodiment, the second electrode extends to a side surface adjacent to the second side surface, extends between the first light-emitting component and the second light-emitting component and extends between the second light-emitting component and the third light-emitting component; the third electrode extends to a side surface adjacent to the third side surface, extends between the first light-emitting component and the second light-emitting component and extends between the second light-emitting component and the third light-emitting component.

In an embodiment, the first electrode is electrically connected to the positive electrode of the first light-emitting component through an ohmic contact material, the second electrode is electrically connected to the positive electrode of the second light-emitting component through an ohmic contact material, and the common electrode is electrically connected to the negative electrode of the first light-emitting component and the negative electrode of the second light-emitting component through an ohmic contact material.

In another aspect, an embodiment of the disclosure provides a production method of a laminated light-emitting unit including following steps: multiple light-emitting chips are provided. Each light-emitting chip includes a light-emitting component, a negative electrode and a positive electrode. The light-emitting component includes a top surface, a bottom surface opposite to the top surface and multiple side surfaces disposed between the top surface and the bottom surface. The negative electrode is electrically connected to a negative electrode of the light-emitting component and disposed on a first side surface of the multiple side surfaces. The positive electrode is electrically connected to a positive electrode of the light-emitting component. The multiple light-emitting chips include a first light-emitting chip and a second light-emitting chip, the first light-emitting chip includes a first connecting electrode disposed on a second side surface of the multiple side surfaces, and the first side surface and the second side surface are different side surfaces. The first connecting electrode is insulated from a first light-emitting component of the first light-emitting chip, and the positive electrode of the first light-emitting chip extends to the bottom surface of the first light-emitting chip. The second light-emitting chip is laminated on the top surface of the first light-emitting chip to make the negative electrode of the first light-emitting chip abut against and be electrically connected to the negative electrode of the second light-emitting chip, thereby forming a common electrode, and to make the positive electrode of the second light-emitting chip abut against and be electrically connected to the first connecting electrode of the first light-emitting chip, thereby forming a second electrode.

In an embodiment, the multiple light-emitting chips further includes a third light-emitting chip, the first light-emitting chip further includes a second connecting electrode spaced apart from the first connecting electrode, the second connecting electrode is insulated from the first light-emitting component of the first light-emitting chip and extends to the bottom surface of the first light-emitting chip. The second light-emitting chip further includes a third connecting electrode aligned with the second connecting electrode, the third connecting electrode is insulated from the second light-emitting component of the second light-emitting chip. The production method of the laminated light-emitting unit further includes the following steps: the third light-emitting chip is laminated on a side of the second light-emitting chip facing away from the first light-emitting chip, thereby making the second connecting electrode, the third connecting electrode and the positive electrode of the third light-emitting chip be sequentially laminated to form a third electrode, and making the negative electrode of the third light-emitting chip abut against and be electrically connected to the negative electrode of the second light-emitting chip.

In an embodiment, the first light-emitting chip is an organic light-emitting chip, the second light-emitting is an inorganic light-emitting chip, and the production method of the laminated light-emitting unit further includes the following steps: the first light-emitting chip is evaporated on a substrate. Then the prepared second light-emitting chip is transferred and connected to the top surface of the first light-emitting chip, thereby laminating the second light-emitting chip on the first light-emitting chip.

In another aspect, an embodiment of the disclosure provides a display panel including an array substrate and the laminated light-emitting unit mentioned above. The laminated light-emitting unit is disposed on the array substrate and connected to the array substrate.

In an embodiment, the display panel further includes a focusing lens, the focusing lens is disposed opposite to the array substrate, and the laminated light-emitting unit is disposed between the focusing lens and the array substrate and corresponds to the focusing lens.

In conclusion, the above embodiments of the disclosure can achieve one or more beneficial effects: multiple light-emitting components are sequentially laminated and corresponding electrical connection relationships are formed, so that multiple light-emitting components can be disposed on the same position to emit light and can be independently controlled to emit light, thereby reducing the occupied area of the light-emitting unit, achieving high-resolution display, and achieving narrow light emission and low color deviation.

Other aspects and features of the disclosure become apparent through the detailed explanation of the attached drawings. However, it should be noted that the attached drawings are only designed for explanatory purposes and not as a limitation of the scope of the disclosure. It should also be noted that unless otherwise indicated, it is not necessary to draw drawings to scale, as they only attempt to conceptually illustrate the structure and process described here.

### BRIEF DESCRIPTION OF DRAWINGS

The following will provide a detailed explanation of the embodiments of the disclosure in conjunction with the attached drawings.

FIG. 1 illustrates a schematic bottom view of a laminated light-emitting unit according to an embodiment of the disclosure.

FIG. 2 illustrates a cross-sectional view of the laminated light-emitting unit illustrated in FIG. 1 along a cutting plane line 1-1.

FIG. 3 illustrates a cross-sectional view of the laminated light-emitting unit illustrated in FIG. 1 along a cutting plane line 2-2.

FIG. 4 illustrates a cross-sectional view of the laminated light-emitting unit illustrated in FIG. 1 along a cutting plane line 1-1 according to another embodiment of the disclosure.

FIG. 5 illustrates a schematic top view of a second light-emitting chip according to an embodiment of the disclosure.

FIG. 6 illustrates a cross-sectional view of the second light-emitting chip illustrated in FIG. 5 along a cutting plane line 3-3.

FIG. 7 illustrates a cross-sectional view of the second light-emitting chip illustrated in FIG. 5 along a cutting plane line 4-4.

FIG. 8 illustrates a schematic bottom view of a first light-emitting chip according to an embodiment of the disclosure.

FIG. 9 illustrates a cross-sectional view of the first light-emitting chip illustrated in FIG. 8 along a cutting plane line 5-5.

FIG. 10 illustrates a schematic top view of a third light-emitting chip according to an embodiment of the disclosure.

FIG. 11 illustrates a schematic structural diagram of a display panel according to an embodiment of the disclosure.

### DESCRIPTION OF REFERENCE NUMERALS

100. laminated light-emitting unit; 101. top surface; 102. bottom surface; 103. side surface; 1031. first side surface; 1032. second side surface; 1033. third side surface; 10. first light-emitting component; 20. second light-emitting component; 30. third light-emitting component; 40. common electrode; 50. first electrode; 60. second electrode; 70. third electrode; 200. light-emitting chip; 210. light-emitting component; 220. negative electrode; 230. positive electrode; 240. first connecting electrode; 250. second connecting electrode; 260. third connecting electrode; 201. first light-emitting chip; 202. second light-emitting chip; 203. third light-emitting chip; 300. display panel; 301. array substrate; 302. focusing lens.

### DETAILED DESCRIPTION OF EMBODIMENTS

In order to make the above purposes, features, and advantages of the disclosure more obvious and understandable, a detailed explanation of the embodiments of the disclosure will be provided below in conjunction with the attached drawings.

In order to enable those skilled in the art to better understand the technical solutions of the disclosure, the following will provide a clear and complete description of the technical solutions in the embodiments of the disclosure in conjunction with the attached drawings. Apparently, the described embodiments are only a part of the embodiments of the disclosure, not all of them. Based on the embodiments in the disclosure, all other embodiments obtained by those skilled in the art without creative labor shall fall within the scope of protection in the disclosure.

It should be noted that the terms “first” and “second” in the description and claims of the disclosure, as well as the attached drawings, are used to distinguish similar objects and do not need to be used to describe a specific order or sequence. It should be understood that the terms used in this way can be interchanged in appropriate cases, so that the embodiments described herein can be implemented in order other than those illustrated or described here. In addition, the terms “including” and “having”, as well as any variations thereof, are intended to cover non-exclusive inclusion, for example, a process, method, system, product, or device that includes a series of steps or units is not necessarily limited to those clearly listed steps or units, but may include other steps or units that are not clearly listed or inherent to the process, method, product, or device.

It should also be noted that the division of multiple embodiments in the disclosure is only for the convenience of description and should not constitute special limitations. The features in various embodiments can be combined and mutually referenced without contradiction.

### Embodiment 1

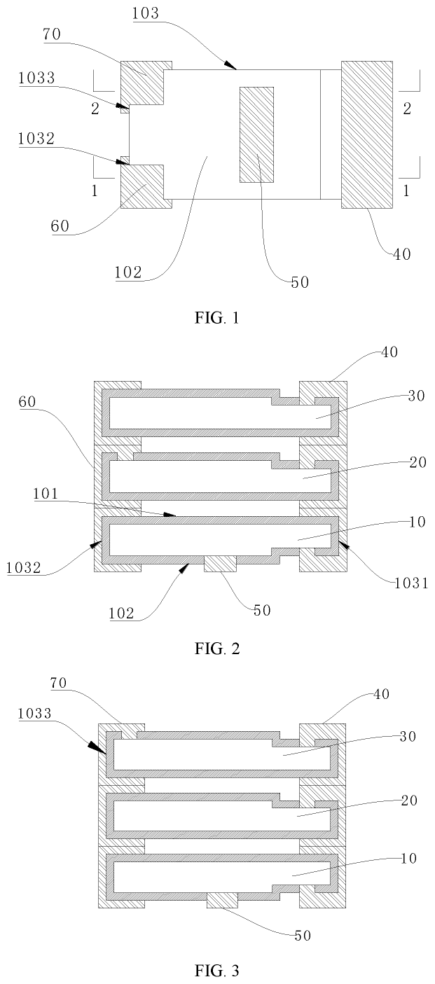

As shown in FIGS. 1 to 3, FIG. 1 illustrates a schematic bottom view of a laminated light-emitting unit 100 according to an embodiment of the disclosure, FIG. 2 illustrates a cross-sectional view of the laminated light-emitting unit 100 illustrated in FIG. 1 along a cutting plane line 1-1, FIG. 3 illustrates a cross-sectional view of the laminated light-emitting unit 100 illustrated in FIG. 1 along a cutting plane line 2-2. The laminated light-emitting unit 100 includes a first light-emitting component 10, a second light-emitting component 20, a common electrode 40, a first electrode 50 and a second electrode 60. The first light-emitting component 10 includes a top surface 101, a bottom surface 102 opposite to the top surface 101 and multiple side surfaces 103 disposed between the top surface 101 and the bottom surface 102. The second light-emitting component 20 is laminated on the top surface 101 of the first light-emitting component 10, the common electrode 40 is disposed on a first side surface 1031 of the multiple side surfaces 103 and two ends of the common electrode 40 are connected to a negative electrode of the first light-emitting component 10 and a negative electrode of the second light-emitting component 20 respectively. The second electrode 60 is disposed on a second side surface 1032 of the multiple side surfaces 103, the first side surface 1031 and the second side surface 1032 are different side surfaces, the second electrode 60 is electrically connected to a positive electrode of the second light-emitting component 20 and insulated from the first light-emitting component 10, and the second electrode 60 extends to the bottom surface 102 of the first light-emitting component 10. The laminated light-emitting unit 100 provided in this embodiment will be further described with FIGS. 1, 2, and 3.

As shown in FIGS. 1, 2, and 3, the first light-emitting component 10 is a hexahedral structure with four side surfaces 103. For example, as shown in FIG. 2, the first side surface 1031 is a right side surface 103 of the first light-emitting component 10, the second side surface 1032 is a left side surface 103 of the first light-emitting component 10, and the first side surface 1031 and the second side surface 1032 are opposite sides. Certainly, in other embodiments, the first side surface 1031 and the second side surface 1032 can be adjacent sides, for example, the first side surface 1031 is the right side surface 103, the second side surface 1032 is a front or a rear side surface 103, and the embodiment is not limited to this.

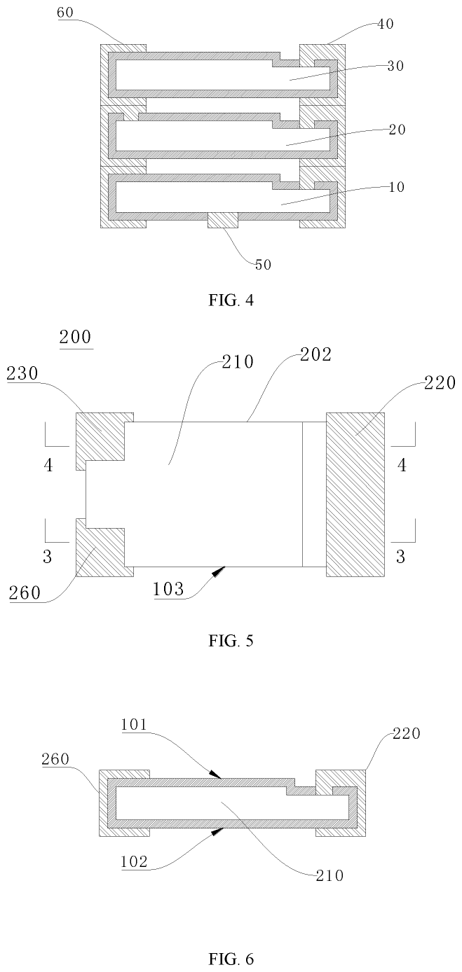

In an embodiment, the first light-emitting component 10 and the second light-emitting component 20 are used to emit light with different colors, and the first light-emitting component 10 and the second light-emitting component 20 include light-emitting functional layers and insulation protection layers surrounding the light-emitting functional layers. As shown in FIGS. 2 and 3, an unfilled part of the first light-emitting component 10 is the light-emitting functional layer, and a monoclinic line filling part is the insulation protection layer. The insulation of the second electrode 60 and the first light-emitting component 10 can be achieved through the insulation protection layer, and the insulation of the first electrode 50 and the second light-emitting component 20 can be achieved through the insulation protection layer (when the first electrode 50 is disposed on the side surface 103). Openings are defined on the insulation protection layers corresponding to positions of positive and negative electrodes of the first light-emitting component 10 and the second light-emitting component 20, so that the common electrode 40 is electrically connected to the negative electrodes of the first light-emitting component 10 and the second light-emitting component 20 through the openings, the first electrode 50 is connected to the positive electrode of the first light-emitting component 10 through the openings, and the second electrode 60 is connected to the positive electrode of the second light-emitting component 20 through the openings. The first light-emitting component 10 can be an inorganic light-emitting structure or an organic light-emitting structure, the second light-emitting component 20 can be the inorganic light-emitting structure, for example, when the first light-emitting component 10 or the second light-emitting component 20 is the inorganic light-emitting structure, the light-emitting functional layer includes a sequentially laminated layer of a N-doped semiconductor layer, a quantum well layer, and a P-doped semiconductor layer, the P-doped semiconductor layer is the positive electrode of the first light-emitting component 10, and the N-doped semiconductor layer is the negative electrode of the first light-emitting component 10, the P-doped semiconductor layer and the N-doped semiconductor layer are also provided with ITO film layers as an ohmic contact material to form an ohmic contact connection. When the first light-emitting component 10 is the organic light-emitting structure, the light-emitting functional layer includes a hole injection layer (HIL), a hole transport layer (HTL), a light-emitting layer (EML), an electron transport layer (ETL), and an electron injection layer (EIL) that are sequentially laminated. The hole injection layer is the positive electrode of the first light-emitting component 10, and the electron injection layer is the negative electrode of the first light-emitting component 10. FIG. 4 illustrates a cross-sectional view of the laminated light-emitting unit 100 illustrated in FIG. 1 along a cutting plane line 1-1 according to another embodiment when the first light-emitting component 10 is the organic light-emitting structure, FIG. 2 illustrates a cross-sectional view of the laminated light-emitting unit 100 illustrated in FIG. 1 along a cutting plane line 1-1 when the first light-emitting component 10 is the inorganic light-emitting structure, and the first light-emitting component 10 is a flip structure. Certainly, here are some examples of the structure of the first light-emitting component 10, which cannot be used as a limiting condition for understanding this embodiment.

In the embodiment, the common electrode 40, the first electrode 50 and the second electrode 60 can be made of commonly used metal electrode materials such as nickel (Ni), platinum (Pt), gold (Au), and can be a single layer structure or a multi-layer structure, this embodiment is not limited to this. As shown in FIGS. 2-3, the first electrode 50 can be disposed on the bottom surface 102 of the first light-emitting component 10 or on the side surface 103 (not shown in figures), and the embodiment is not limited to this. As shown in FIGS. 2-3, a three-layer structure is provided, the first light-emitting component 10 and the second light-emitting component 20 of the embodiment are a first layer and a second layer of the three-layer structure from bottom to top, respectively. Certainly, in other embodiments of the disclosure, the first light-emitting component 10 and the second light-emitting component 20 can be a second layer and a third layer of the three-layer structure from bottom to top as shown in FIG. 3, and the embodiment is not limited to this. In addition, the embodiment does not limit the number of layers of the laminated light-emitting unit 100, and the laminated light-emitting unit 100 can also include three layers as shown in FIGS. 2 and 3, four layers or even more layers. The common electrode 40, the first electrode 50 and the second electrode 60 all extend to the bottom surface 102 of the first light-emitting component 10, which is conducive to the welding of the laminated light-emitting unit 100.

In the embodiment, the first light-emitting component 10 and the second light-emitting component 20 of the laminated light-emitting unit 100 are used to emit light with different colors, for example, the first light-emitting component 10 emits red light, and the second light-emitting component 20 emits green light. When the laminated light-emitting unit 100 is working, the common electrode 40 and the first electrode 50 are energized, and the second electrode 60 is not energized, therefore, the first light-emitting component 10 is energized to emit red light, while the second light-emitting component 20 does not emit light, thereby the laminated light-emitting unit 100 can emit red light. Or the common electrode 40 and the second electrode 60 are energized, and the first electrode 50 is not energized, the first light-emitting component 10 cannot emit light, the second light-emitting component 20 can emit green light, thereby the laminated light-emitting unit 100 can emit green light. Alternatively, when both the first electrode 50 and the second electrode 60 are energized with the common electrode 40, the red light emitted by the first light-emitting component 10 and the green light emitted by the second light-emitting component 20 mix to make the laminated light-emitting unit 100 to emit a mixed light of red and green. Certainly, the above is only an example, and the embodiment does not limit the specific emitting colors of the first light-emitting component 10 and the second light-emitting component 20. The embodiment adopts a structure of laminating the first light-emitting component 10 and the second light-emitting component 20, and the first light-emitting component 10 and the second light-emitting component 20 can be separately controlled to emit light, so that each laminated light-emitting unit 100 can achieve multiple light-emitting methods. Compared with traditional light-emitting structures, it can reduce the area occupied by each chip on the display panel, which is conducive to achieving high-resolution display.

In an embodiment, the laminated light-emitting unit 100 further includes a third light-emitting component 30 and a third electrode 70, the third light-emitting component 30 is laminated on a side of the second light-emitting component 20 facing away from the first light-emitting component 10. The third electrode 70 is spaced apart from the first electrode 50, the second electrode 60 and the common electrode 40, and the third electrode 70 is disposed on a third side surface 1033 of the multiple side surfaces 103. The third side surface 1033 and the first side surface 1031 are different sides, the third electrode 70 is electrically connected to a positive electrode of the third light-emitting component 30 and the common electrode 40 is electrically connected to the negative electrode of the third light-emitting component 30. The third electrode 70 is insulated from the first light-emitting component 10 and the second light-emitting component 20, and the third electrode 70 extends to the bottom surface 102 of the first light-emitting component 10. The third side surface 1033 and the second side surface 1032 can be the same side or different sides, as shown in FIGS. 2-3, the third side surface 1033 and the second side surface 1032 are a left side surface of the first light-emitting component 10, as the direction of FIG. 1, the second electrode 60 is disposed at a lower left corner of FIG. 1, and the third electrode 70 is disposed at an upper left corner of FIG. 1. In other embodiments, the first side surface 1031 is the right side surface of the first light-emitting component 10, the second side 1032 is the front side surface of the first light-emitting component 10, and the third side surface 1033 is a rear side surface of the first light-emitting component 10, the embodiment is not limited to this. The first electrode 50 can be disposed on the bottom surface 102 of the first light-emitting component 10 or on a different side surface from the first side surface 1031, as long as it meets the requirements of spacing with the second electrode 60 and the third electrode 70. And the third light-emitting component 30 is an inorganic light-emitting structure, referring to the description above that the first light-emitting component 10 and the second light-emitting component 20 are inorganic light-emitting structures, the third light-emitting component 30 is used to emit light with a different color from the first light-emitting component 10 and the second light-emitting component 20. Specifically, when the laminated light-emitting unit 100 is applied to RGB full color display panels, the first light-emitting component 10, the second emitting light-emitting 20 and the third light-emitting component 30 each emit one of the red, blue, and green lights, or other color combinations. Due to the fact that red inorganic light-emitting structures generally use gallium arsenide semiconductors with poor light transmittance, it is preferable for the first light-emitting component 10 to be a red light-emitting component, the second light-emitting component 20 to be a green light-emitting component, and the third light-emitting component 30 to be a blue light-emitting component in the RGB combination to ensure the light-emitting effect of the laminated light-emitting unit 100. The laminated light-emitting unit 100 of the embodiment is applied to the RGB display panel, only one laminated light-emitting unit 100 needs to be provided for the position of light points of the original RGB three sub-pixels, which is equivalent to reducing the area occupied by each pixel position to about one-third of the original RGB three sub-pixels, and correspondingly improving the resolution, which is conducive to achieving high-resolution display. And the RGB three color light in each pixel is emitted from the same position of the light points, which is beneficial for improving the color deviation caused by the RGB three color light emitted from different positions in existing displays. When the laminated light-emitting unit 100 includes a four layer or more layer structure, reference can also be made to the embodiment.

In an embodiment, as shown in FIGS. 1-3, the second electrode 60 extends to a side surface 103 adjacent to the second side surface 1032, extends between the first light-emitting component 10 and the second light-emitting component 20, extends between the second light-emitting component 20 and the third light-emitting component 30, and the second electrode 60 further can extend to a side of the third light-emitting component 30 facing away from the second light-emitting component 20. The third electrode 70 extends to a side surface 103 adjacent to the third side surface 1033, extends between the first light-emitting component 10 and the second light-emitting component 20 and extends between the second light-emitting component 20 and the third light-emitting component 30. The common electrode 40 also extends between the first light-emitting component 10 and the second light-emitting component 20, and extends between the second light-emitting component 20 and the third light-emitting component 30. For example, the second side surface 1032 is a side surface 103 on a left side of the first light-emitting component 10 (the bottom left of FIG. 1), and the second electrode 60 further extends to a side surface 103 adjacent to the left side (such as an upper edge of FIG. 1, corresponding to a front surface of FIG. 2). The third side surface 1033 is the side surface 103 on the left side of the first light-emitting component 10 (the top left of FIG. 1), and the third electrode 70 further extends to the side surface 103 adjacent to the left side (such as a lower edge of FIG. 1, corresponding to a back surface of FIG. 3). The area of the common electrode 40, the second electrode 60, and the third electrode 70 can be increased to make a better conductivity. It should be noted that when the first electrode 50 is also disposed on the side surface 103, an extension method of the first electrode 50 similar to the second electrode 60 or the third electrode 70 can be used, and this embodiment does not repeat.

### Embodiment 2

A production method of a laminated light-emitting unit includes the following steps.

S1: multiple light-emitting chips are provided, for example, the multiple light-emitting chips 200 as shown in FIG. 5 or 8, each light-emitting chip 200 includes a light-emitting component 210, a negative electrode 220 and a positive electrode 230. The light-emitting component 210 includes a top surface 101, a bottom surface 102 opposite to the top surface 101 and multiple side surfaces 103 disposed between the top surface 101 and the bottom surface 102. The negative electrode 220 is electrically connected to a negative electrode of the light-emitting component 210 and disposed on a first side surface 1031 of the multiple side surfaces 103. The positive electrode 230 is electrically connected to a positive electrode of the light-emitting component 210. The multiple light-emitting chips 200 include a first light-emitting chip 201 and a second light-emitting chip 202, the first light-emitting chip 201 includes a first connecting electrode 240 and the first connecting electrode 240 is disposed on a second side surface 1032 of the multiple side surfaces 103, and the first side surface 1031 and the second side surface 1032 are different side surfaces. The first connecting electrode 240 is insulated from a first light-emitting component 10 of the first light-emitting chip 201, and the positive electrode 230 of the first light-emitting chip 201 extends to a bottom surface 102 of the first light-emitting component 10 of the first light-emitting chip 201.

S2: the second light-emitting chip 202 is laminated on a top surface 101 of the first light-emitting chip 201 to make the negative electrode 220 of the first light-emitting chip 201 abut against and be electrically connected to the negative electrode 220 of the second light-emitting chip 202, thereby forming a common electrode 40, and to make the positive electrode 230 of the second light-emitting chip 202 abut against and be electrically connected to the first connecting electrode 240 of the first light-emitting chip 201, thereby forming a second electrode 60.

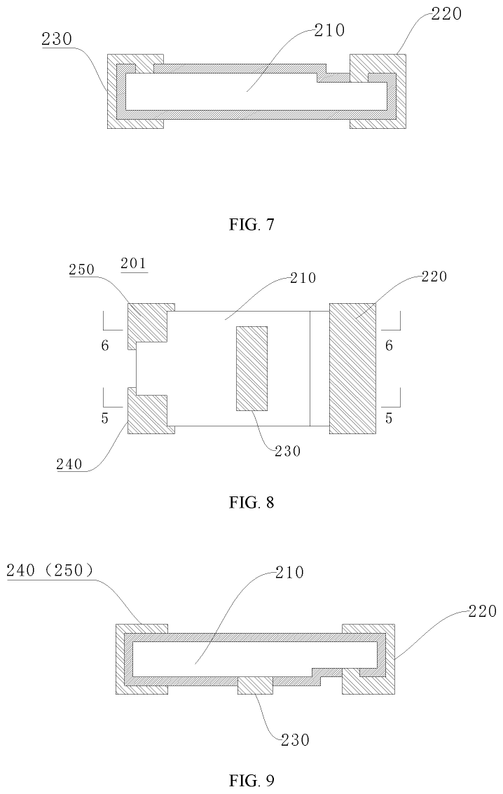

FIG. 8 illustrates a schematic bottom view of a first light-emitting chip 201, FIG. 9 illustrates a cross-sectional view of the first light-emitting chip 201 illustrated in FIG. 8 along a cutting plane line 5-5 (or 6-6), FIG. 5 illustrates a schematic top view of a second light-emitting chip 202, FIG. 6 illustrates a cross-sectional view of the second light-emitting chip 202 illustrated in FIG. 5 along a cutting plane line 3-3, and FIG. 7 illustrates a cross-sectional view of the second light-emitting chip 202 illustrated in FIG. 5 along a cutting plane line 4-4. It can be seen that the positive electrode 230 of the first light-emitting chip 201 is disposed on the bottom surface 102 of the first light-emitting component 10, while the positive electrode 230 of the second light-emitting chip 202 is disposed on the second side surface 1032. Certainly, the embodiment is not limited to this, and in some embodiments, the positive electrode 230 of the first light-emitting chip 201 can also be disposed on the side surface 103. The production method of the laminated light-emitting unit can be used to prepare the laminated light-emitting unit 100 as described in the embodiment 1, the descriptions of the first light-emitting component 10, the second light-emitting component 20, the common electrode 40, and the second electrode 60 can be referred to in the embodiment 1, and do not be repeated here. In the production method of the laminated light-emitting unit, for example, the positive electrode 230 of the first light-emitting chip 201 is disposed on the bottom surface 102 of the first light-emitting component 10, and the positive electrode 230 of the first light-emitting chip 201 is equivalent to the first electrode 50 in the laminated light-emitting unit 100. When the positive electrode 230 of the first light-emitting chip 201 is disposed on the side surface 103 of the first light-emitting component 10, the positive electrode 230 of the first light-emitting chip 201 can form the first electrode 50 of the laminated light-emitting unit 100 together with the electrode material at the corresponding position on the second light-emitting chip 202. Certainly, the first electrode 50 is insulated from the second light-emitting component 20.

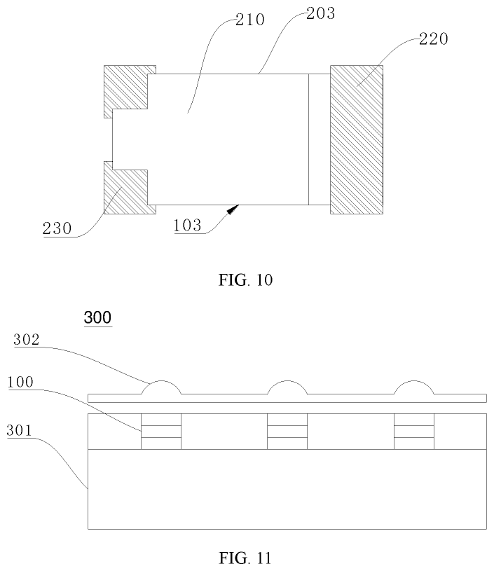

In an embodiment, the multiple light-emitting chips 200 further includes a third light-emitting chip 203, the first light-emitting chip 201 further includes a second connecting electrode 250 spaced apart from the first connecting electrode 240, the second connecting electrode 250 is insulated from the first light-emitting component 10 of the first light-emitting chip 201 and extends to the bottom surface 102 of the first light-emitting chip 201. The second light-emitting chip 202 further includes a third connecting electrode 260 aligned with the second connecting electrode 250, the third connecting electrode 260 is insulated from the second light-emitting component 20 of the second light-emitting chip 202, and the production method of the laminated light-emitting unit further includes S3: the third light-emitting chip 203 is laminated on a side of the second light-emitting chip 202 facing away from the first light-emitting chip 201, then the second connecting electrode 250 and the third connecting electrode 260 are laminated sequentially with a positive electrode 230 of the third light-emitting chip 203 to form a third electrode 70, and a negative electrode 220 of the third light-emitting chip 203 and the negative electrode 220 of the second light-emitting chip 202 are abutted against and electrically connected. FIG. 10 illustrates a schematic top view of a third light-emitting chip 230, it can be seen that the positive electrode 230 is aligned with the third connecting electrode 260 of the second light-emitting chip 202.

In an embodiment, the first light-emitting chip 201 can be an organic light-emitting chip such as an OLED chip, or an inorganic light-emitting chip such as a micro-LED chip. The second light-emitting chip 202 and the third light-emitting chip 203, for example, are inorganic light-emitting chips. The production method of the laminated light-emitting unit further includes the following steps.

S11: the first light-emitting chip 201 is evaporated on a substrate.

S21: the prepared second light-emitting chip 202 is transferred and connected to the top surface of the first light-emitting chip 201, thereby laminating the second light-emitting chip 202 on the first light-emitting chip 201.

The production method of the laminated light-emitting unit, for example, further includes the following step S31: the prepared third light-emitting chip 203 is transferred and connected to a top surface of the second light-emitting chip 202 facing away from the first light-emitting chip 201, thereby laminating the third light-emitting chip 203 on the second light-emitting chip 202.

In the S11, the substrate is an array substrate of a display panel, which is provided with a driving circuit layer for driving the emission of the laminated light-emitting unit. The first light-emitting component 10 of the first light-emitting chip 201 is the organic light-emitting component, including HIL, HTL, EML, ETL and EIL that are sequentially laminated, and can be formed through the evaporating.

The embodiment 2 can be used to prepare a laminated light-emitting unit 100 as described in the embodiment 1, which has the same beneficial effect as the embodiment 1 and is simple in process.

### Embodiment 3

As shown in FIG. 11, a display panel 300 includes an array substrate 301 and multiple laminated light-emitting units 100, each laminated light-emitting unit 100 can be any of the above embodiment 1, and each laminated light-emitting unit 100 is disposed on the array substrate 301 and connected to the array substrate 301. The array substrate 301 is provided with a driving circuit layer for driving the laminated light-emitting units 100, which may include wires (such as data lines, scan lines), thin film transistors (TFT), and other suitable components such as capacitors. As shown in FIG. 11, three laminated light-emitting units 100 are disposed on the array substrate 301. Certainly, this embodiment is only for example and does not limit the number of the laminated light-emitting units 100. When the laminated light-emitting units 100 are disposed on the array substrate 301, the installation direction is such that the first light-emitting component 10 is adjacent to the array substrate 301, the second light-emitting component 10 is disposed on a side of the first light-emitting component 10 facing away from the array substrate 301, and parts of the common electrode 40, the first electrode 50, and the second electrode 60 of each laminated light-emitting unit 100 extending to the bottom surface 102 of the first light-emitting component 10 are electrically connected to the driving circuit layer on the array substrate 301, respectively, thereby the laminated light-emitting unit 100 is electrically connected to the driving circuit layer on the array substrate 301. For example, the first electrode 50 and the second electrode 60 are electrically connected to different TFTs, and the common electrode 40 is connected to a common electrode on the driving circuit layer to achieve separate control driving of the first light-emitting component 10 and the second light-emitting component 20. When the laminated light-emitting unit 100 further includes the third light emitting component 30 and the third electrode 70, a part of the third electrode 70 extending to the bottom surface 102 of the first light emitting component 10 is electrically connected to another different TFT on the driving circuit layer of the array substrate 301 to achieve separate control driving of the first light-emitting component 10, the second light-emitting component 20, and the third light-emitting component 30. Specifically, taking a RGB display as an example, in the embodiment, the first light-emitting component 10 is a red light-emitting component, the second light-emitting component 20 is a green light-emitting component, and the third light-emitting component 30 is a blue light-emitting component, which corresponds to the position of each laminated light-emitting unit 100 on the display panel 300. By independently controlling different light-emitting components to emit light separately, red light, green light, blue light, red green mixed light, and blue green mixed light, red blue mixed light, white light, and other color mixing effects can be achieved. For the existing RGB display panel, which requires setting three light points of R, G and B at each pixel position, the display panel 300 provided in this embodiment only needs to disposed one laminated light-emitting unit 100 at the each pixel position to achieve RGB full color effect. The light points at each pixel position occupy about one-third of the original area of the existing RGB display panel, which can achieve higher resolution display. Moreover, the existing RGB display panel has a structure where each pixel position emits three colors of light from three different positions. The mixing effect of the three colors of light varies under different visual angles (left, right, or middle), resulting in significant color deviation. The display panel 300 provided in the embodiment of the disclosure emits three colors of light from the same position, which can greatly reduce color deviation. Certainly, in the embodiment of the disclosure, the number of layers of the laminated light-emitting unit 100 is not limited to this, more layers can also achieve smaller occupied area and higher resolution.

In an embodiment, as shown in FIG. 11, the display panel 300 further includes focusing lenses 302, the focusing lenses 302 are disposed opposite to the array substrate 301, and each laminated light-emitting unit 100 corresponds to one of the focusing lenses 302 and is disposed between the corresponding focusing lens 302 and the array substrate 301. For example, as shown in FIG. 11, the positions of the three laminated light-emitting units 100 respectively correspond to the focusing lenses 302, which can further limit the light-emitting angle of the laminated light-emitting units 100 and achieve a narrow light emitting effect.

The embodiment 3 of the disclosure adopts the laminated light-emitting unit 100 provided by the embodiment 1, which has at least the same beneficial effect as the embodiment 1, and does not be repeated here.

The above is only some preferred embodiments of the disclosure and is not intended to limit the disclosure. Although the disclosure has been disclosed in the some preferred embodiments, which are not intended to limit the disclosure. Those skilled in the art may, within the scope of the technical solutions of the disclosure, make some changes or modifications to equivalent embodiments using the disclosed technical content. Any simple changes, equivalent changes or modifications made to the above embodiments based on the technical content of the disclosure without departing from the technical solutions of the disclosure will still fall within the scope of the technical solutions of the disclosure.

What is claimed is:

1. A laminated light-emitting unit, comprising:
a first light-emitting component, comprising a top surface, a bottom surface opposite to the top surface and a plurality of side surfaces disposed between the top surface and the bottom surface;
a second light-emitting component, laminated on the top surface of the first light-emitting component;
a common electrode, disposed on a first side surface of the plurality of side surfaces and connected to a negative electrode of the first light-emitting component and a negative electrode of the second light-emitting component; wherein the common electrode extends to the bottom surface of the first light-emitting component;
a second electrode, disposed on a second side surface of the plurality of side surfaces; wherein the first side surface and the second side surface are different side surfaces, the second electrode is electrically connected to a positive electrode of the second light-emitting component and insulated from the first light-emitting component, and the second electrode extends to the bottom surface of the first light-emitting component; and
a first electrode, spaced apart from the common electrode and the second electrode, wherein the first electrode is electrically connected to a positive electrode of the first light-emitting component and insulated from the second light-emitting component.

2. The laminated light-emitting unit as claimed in claim 1, further comprises:
a third light-emitting component, laminated on a side of the second light-emitting component facing away from the first light-emitting component;
a third electrode, spaced apart from the first electrode, the second electrode and the common electrode; wherein the third electrode is disposed on a third side surface of the plurality of side surfaces; the third side surface and the first side surface are different sides, the third electrode is electrically connected to a positive electrode of the third light-emitting component and insulated from the first light-emitting component and the second light-emitting component, and the third electrode extends to the bottom surface of the first light-emitting component;
wherein the common electrode is electrically connected to a negative electrode of the third light-emitting component, the first electrode and the second electrode are insulated from the third light-emitting component, and the first electrode is disposed on the bottom surface of the first light-emitting component.

3. The laminated light-emitting unit as claimed in claim 1, wherein the first light-emitting component and the second light-emitting component are inorganic light-emitting structures, and the first electrode is disposed on the second side surface and extends to the bottom surface of the first light-emitting component.

4. The laminated light-emitting unit as claimed in claim 1, wherein the first light-emitting component and the second light-emitting component are inorganic light-emitting structures, and the first electrode is disposed on the bottom surface of the first light-emitting component.

5. The laminated light-emitting unit as claimed in claim 1, wherein the second light-emitting component is an inorganic light-emitting structure, the first light-emitting component is an organic light-emitting structure, and the first electrode is disposed on the bottom surface of the first light-emitting component.

6. The laminated light-emitting unit as claimed in claim 2, wherein the first light-emitting component, the second light-emitting component and the third light-emitting component are inorganic light-emitting structures.

7. The laminated light-emitting unit as claimed in claim 2, wherein the second light-emitting component and the third light-emitting component are inorganic light-emitting structures, and the first light-emitting component is an organic light-emitting structure.

8. The laminated light-emitting unit as claimed in claim 2, wherein the first light-emitting component is a red light-emitting component, the second light-emitting component is a green light-emitting component, and the third light-emitting component is a blue light-emitting component.

9. The laminated light-emitting unit as claimed in claim 2, wherein the second electrode extends to a side surface adjacent to the second side surface, extends between the first light-emitting component and the second light-emitting component and extends between the second light-emitting component and the third light-emitting component; the third electrode extends to a side surface adjacent to the third side surface, extends between the first light-emitting component and the second light-emitting component and extends between the second light-emitting component and the third light-emitting component.

10. The laminated light-emitting unit as claimed in claim 1, wherein the first electrode is electrically connected to the positive electrode of the first light-emitting component through an ohmic contact material, the second electrode is electrically connected to the positive electrode of the second light-emitting component through an ohmic contact material, and the common electrode is electrically connected to the negative electrode of the first light-emitting component and the negative electrode of the second light-emitting component through an ohmic contact material.

11. The laminated light-emitting unit as claimed in claim 1, wherein the first side surface and the second side surface are opposite sides.

12. The laminated light-emitting unit as claimed in claim 1, wherein the first side surface and the second side surface are adjacent sides.

13. A production method of a laminated light-emitting unit, comprising:
providing a plurality of light-emitting chips, wherein each light-emitting chip comprises:
a light-emitting component, comprising: a top surface, a bottom surface opposite to the top surface, and a plurality of side surfaces disposed between the top surface and the bottom surface;
a negative electrode, electrically connected to a negative electrode of the light-emitting component and disposed on a first side surface of the plurality of side surfaces; and
a positive electrode, electrically connected to a positive electrode of the light-emitting component;
wherein the plurality of light-emitting chips comprise a first light-emitting chip and a second light-emitting chip, the first light-emitting chip further comprises a first connecting electrode disposed on a second side surface of the plurality of side surfaces, and the first side surface and the second side surface are different side surfaces; the first connecting electrode is insulated from a first light-emitting component of the first light-emitting chip, and the positive electrode of the first light-emitting chip extends to the bottom surface of the first light-emitting component of the first light-emitting chip;
laminating the second light-emitting chip on the top surface of the first light-emitting chip to make the negative electrode of the first light-emitting chip abut against and be electrically connected to the negative electrode of the second light-emitting chip, thereby forming a common electrode, and to make the positive electrode of the second light-emitting chip abut against and be electrically connected to the first connecting electrode of the first light-emitting chip, thereby forming an electrode.

14. The production method of the laminated light-emitting unit as claimed in claim 13, wherein the plurality of light-emitting chips further comprise a third light-emitting chip, the first light-emitting chip further comprises a second connecting electrode spaced apart from the first connecting electrode, the second connecting electrode is insulated from the first light-emitting component of the first light-emitting chip and extends to the bottom surface of the first light-emitting chip; the second light-emitting chip further comprises a third connecting electrode aligned with the second connecting electrode, the third connecting electrode is insulated from the second light-emitting component of the second light-emitting chip, and the production method of the laminated light-emitting unit further comprises:
laminating the third light-emitting chip on a side of the second light-emitting chip facing away from the first light-emitting chip, thereby making the second connecting electrode, the third connecting electrode and the positive electrode of the third light-emitting chip be sequentially laminated to form another electrode, and making the negative electrode of the third light-emitting chip abut against and be electrically connected to the negative electrode of the second light-emitting chip.

15. The production method of the laminated light-emitting unit as claimed in claim 13, wherein the first light-emitting chip is an organic light-emitting chip, the second light-emitting chip is an inorganic light-emitting chip, and the production method of the laminated light-emitting unit comprises:
evaporating the first light-emitting chip on a substrate;
transferring and connecting the second light-emitting chip to the top surface of the first light-emitting chip, thereby laminating the second light-emitting chip on the first light-emitting chip.

16. The production method of the laminated light-emitting unit as claimed in claim 14, wherein the first light-emitting chip is an organic light-emitting chip, the second light-emitting chip and the third light-emitting chip are inorganic light-emitting chips, and the production method of the laminated light-emitting unit comprises:
evaporating the first light-emitting chip on a substrate;
transferring and connecting the second light-emitting chip to the top surface of the first light-emitting chip, thereby laminating the second light-emitting chip on the first light-emitting chip; and
transferring and connecting the third light-emitting chip to the side of the second light-emitting chip facing away from the first light-emitting chip, thereby laminating the third light-emitting chip on the second light-emitting chip.

17. A display panel, comprising:
an array substrate;
the laminated light-emitting unit as claimed in claim 1, wherein the laminated light-emitting unit is disposed on the array substrate and connected to the array substrate.

18. The display panel as claimed in claim 17, wherein the display panel further comprises a focusing lens, the focusing lens is disposed opposite to the array substrate, and the laminated light-emitting unit is disposed between the focusing lens and the array substrate and corresponds to the focusing lens.

19. The display panel as claimed in claim 17, wherein the laminated light-emitting unit further comprises a third light-emitting component and a third electrode, the third light-emitting component is laminated on a side of the second light-emitting component facing away from the first light-emitting component; the third electrode is spaced apart from the first electrode, the second electrode and the common electrode; wherein the third electrode is disposed on a third side surface of the plurality of side surfaces; the third side surface and the first side surface are different sides, the third electrode is electrically connected to a positive electrode of the third light-emitting component and insulated from the first light-emitting component and the second light-emitting component, and the third electrode extends to the bottom surface of the first light-emitting component;
wherein the common electrode is electrically connected to a negative electrode of the third light-emitting component, the first electrode and the second electrode are insulated from the third light-emitting component, and the first electrode is disposed on the bottom surface of the first light-emitting component.

20. The display panel as claimed in claim 19, wherein the second electrode extends to a side surface adjacent to the second side surface, extends between the first light-emitting component and the second light-emitting component and extends between the second light-emitting component and the third light-emitting component; the third electrode extends to a side surface adjacent to the third side surface, extends between the first light-emitting component and the second light-emitting component and extends between the second light-emitting component and the third light-emitting component.
